(19) United States
(12) Patent Application Publication
(10) Pub. No.: US 2014/0091822 A1
(43) Pub. Date: Apr. 3, 2014

(54) BLADE TYPE MICRO PROBE AND METHOD OF MANUFACTURING THE SAME

(71) Applicants: Horng-Jee Wang, Hsinchu County (TW); Ya-Ru Huang, Hsinchu County (TW)

(72) Inventors: Horng-Jee Wang, Hsinchu County (TW); Ya-Ru Huang, Hsinchu County (TW)

(21) Appl. No.: 13/629,980

(22) Filed: Sep. 28, 2012

(51) Int. Cl. G01R 1/067; G01R 3/00

(52) U.S. Cl. 324/755.01; 164/46

(57) ABSTRACT

A blade type micro probe and a method of manufacturing the same are disclosed. The method includes forming a plating seed layer on a substrate, a first blade structure on the plating seed layer and a second blade structure on the first blade structure, wherein the first blade structure includes a first second patterned photo resist layer and a metal layer filling up the voids in the first second patterned photo resist layer and the second blade structure includes a second patterned photo resist layer and an another metal layer filling up the voids in the second patterned photo resist layer, then removing the first and second patterned photo resist layers, and finally removing the plating seed layer and the substrate, thereby forming the blade type micro probe. The first patterned photo resist layer is different from the second patterned photo resist layer in shape.

### BACKGROUND OF THE INVENTION

1. Field of the Invention

The present invention generally relates to a micro probe and a method of manufacturing the same, and more specifically to a blade type micro probe used to test integrated circuits and electronic devices and a method of manufacturing the same.

2. The Prior Arts

In general, a high performance probe is needed to test a high performance electrical device such as VLSI and ULSI. For example, a probe card is applied to the integrated circuits before being packaged to test the electrical function of the bare chips through a probe to exclude bad chips. Therefore, the test process has a significant effect on the cost of manufacturing the integrated circuits. In other words, the probe card is an interface to the tester and the wafer. Each device under test needs at least one corresponding probe card and the purpose of the test is to avoid possible waste by preventing the bad chips from being delivered to the following package process.

Conventionally, an epoxy ring probe card as described in U.S. Pat. No. 4,757,256 has been broadly accepted by the industries because of several advantages like less amount, versatile and flexible process of manufacturing. Such probe card is manually assembled to manufacture by placing the probes one by one. However, for fine pitch and high pin counts, the probes have to be placed in a manner of three-dimensional multi-layer. Each probe may encounter different pressing force as a result that the probe often needs to be repaired. Another probe disclosed in U.S. Pat. No. 6,072,190 and 2007/0024298 A1 is a floating arm probe, which is implemented by manufactured all probes at one time. Such probe has several aspects like high precision, fine pitch and high pin counts. However, the probe can not be repaired or replaced when it is damaged.

Therefore, a new probe structure with the advantage in the prior arts and able to overcome the above-mentioned shortcomings to meet the requirement of high pin counts and fine pitch is needed.

### SUMMARY OF THE INVENTION

A primary objective of the present invention is to provide a blade type micro probe includes a first blade structure and a second blade structure. The first blade structure including a first floating arm part, a first connection part and a first base part. The first floating arm part has a shape of a strip and a height less than a height of the first connection part and the first base part. The first floating arm part extends from one side of the first connection part with a shape of a slab. The first base part has a shape of a slab and extends from another side of the first connection part to connect to an electrical conversion plate outside so as to connect to a tester.

The second blade structure includes a second floating arm part, a second connection part, a second base part, a pin socket and a contact part. The second connection part and the second base part have the same shape as that of the first connection part and the first base part. The second connection part and the second base part are located at the same position as the first connection part and the first base part. The second floating arm part has a shape of a strip similar to the shape of the first floating arm part, and is longer than the shape of the first floating arm part and the third floating arm part. The pin socket is provided at one end of the second floating part extending from the second connection arm part in an upward direction. The contact part extends upward at the pin socket to contact with a bonding pad of a chip.

Furthermore, a third blade structure identical to the first blade structure is provided at another side of the second blade structure so as to form a stacked structure.

Another objective of the present invention is to provide a method of manufacturing the blade type micro probe, including the steps of forming a plating seed layer on a substrate, then forming a first blade structure and a second blade structure with the formation of a first patterned photo resist layer and a second patterned photo resist layer and the processes of plating and polishing, wherein the first patterned photo resist layer and the second patterned photo resist layer are different in shape, and finally, removing the substrate and the plating seed layer to form the blade type micro probe.

Additionally, the method of the present invention includes a step of forming a third blade structure, which is identical to step of forming the first blade structure after the second blade structure is formed.

Moreover, the first blade structure, the second blade structure and the third blade structure can be formed by alternative steps of forming a patterned photo resist layer, plating a first metal layer, removing the patterned photo resist layer, plating a second metal layer and performing the polishing process so as to form a stacked structure from bottom to up with a first metal pattern layer/the first blade structure, a second metal pattern layer/the second blade structure, and a third metal pattern layer/the third blade structure, wherein the second blade structure and the first blade structure are different, and the third blade structure is identical to the first blade structure. Finally, the first metal pattern layer, the second metal pattern layer and the third metal pattern layer are removed by an etching agent which does not react with the first blade structure, the second blade structure and the third blade structure, and the substrate and the plating seed layer are then removed to acquire the blade type micro probe.

One aspect of the micro probe and the method of manufacturing the same according to the present invention is that the micro probe can be conveniently placed and easily replaced in view of structure to meet the requirements of the test of the integrated circuits and electronic devices, such as high pin counts, fine pitch. Additionally, the method can be easily implemented in mass production to reduce the cost.

### BRIEF DESCRIPTION OF THE DRAWINGS

The present invention can be understood in more detail by reading the subsequent detailed description in conjunction with the examples and references made to the accompanying drawings, wherein:

FIG. 1 illustrates a perspective view of the first embodiment of a blade type micro probe according to the present invention;

FIGS. 2A to 2D show perspective views of modification of the first embodiment of the blade type micro probe according to the present invention;

FIG. 3 illustrates a perspective view of the second embodiment of the blade type micro probe according to the present invention;

FIGS. 4A to 4D show perspective views of the modification of the second embodiment of blade type micro probe according to the present invention;

FIG. 5 illustrates a flow chart of the method of manufacturing the first embodiment of the blade type micro probe according to the present invention;

FIGS. 6A to 6H and 7A to 7D are sequentially cross sectional views of the first embodiment of the blade type micro probe illustrating the method according to the present invention;

FIG. 8 illustrates a flow chart of the method of manufacturing the second embodiment of the blade type micro probe according to the present invention; and

FIGS. 9A to 9H and 10A to 10C are sequentially cross sectional views of the second embodiment of the blade type micro probe to illustrating the method according to the present invention.

### DETAILED DESCRIPTION OF THE PREFERRED EMBODIMENT

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

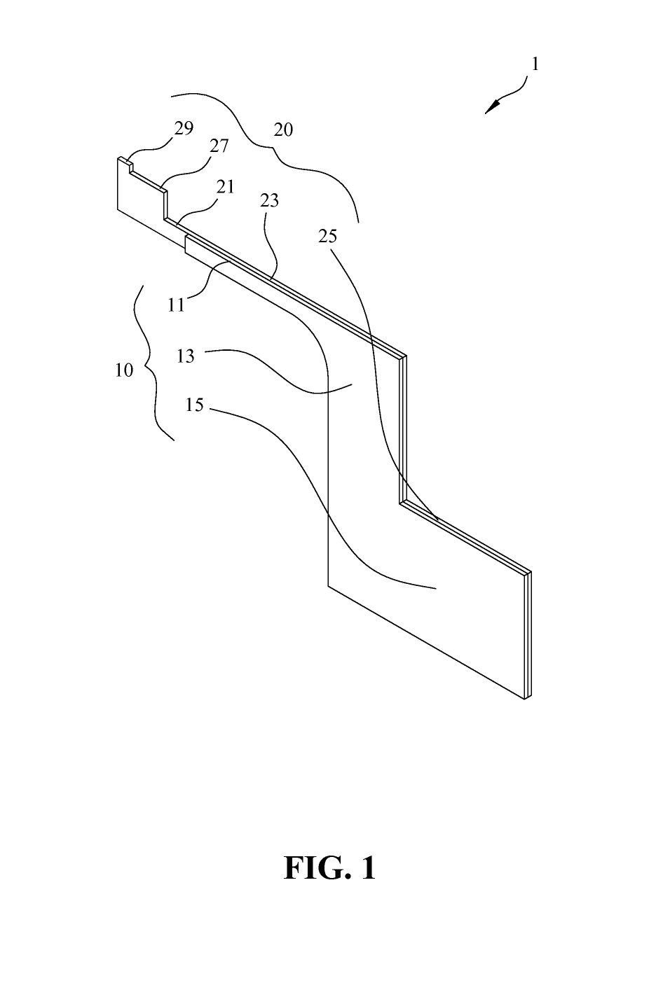

Please refer to FIG. 1, illustrating the perspective view of the first embodiment of the blade type micro probe according to the present invention. As shown in FIG. 1, the blade type micro probe 1 of the present invention includes a first blade structure 10 and a second blade structure 20, which are connected to each other. The first blade structure 10 includes a first floating arm part 11, a first connection part 13 and a first base part 15. The first floating arm part 11 has a shape of a strip and a width less than the width of the first connection part 13 and the first base part 15. The first floating arm part 11 extends from one side of the first connection part 13 with a shape of a slab. The first base part 15 has a shape of a slab and extends from another side of the first connection part 13 to connect to an electrical conversion plate outside so as to electrically connect to a tester (not shown).

The second blade structure 20 includes a second floating arm part 21, a second connection part 23, a second base part 25, a pin socket 27 and a contact part 29. The second base part 25 and the first base part 15 are located at the same position and are tightly attached to each other. The second floating arm part 21 and the second connection part 23 are connected to the first floating arm part 11 and the first connection part 13, respectively. The second floating arm part 21 and the first floating arm part 11 basically have a shape of a strip, but the second floating arm part 21 is longer than the first floating arm part 11. Additionally, the widths thereof are identical or different. The second connection part 23 and the first connection part 13 have the same length and the widths thereof are identical or different. The pin socket 27 is provided at one end of the second floating part 21 and extends from the second connection arm part 23 in an upward direction. The contact part 29 is provided upward at the pin socket 27 to contact with a bonding pad of a chip (not shown).

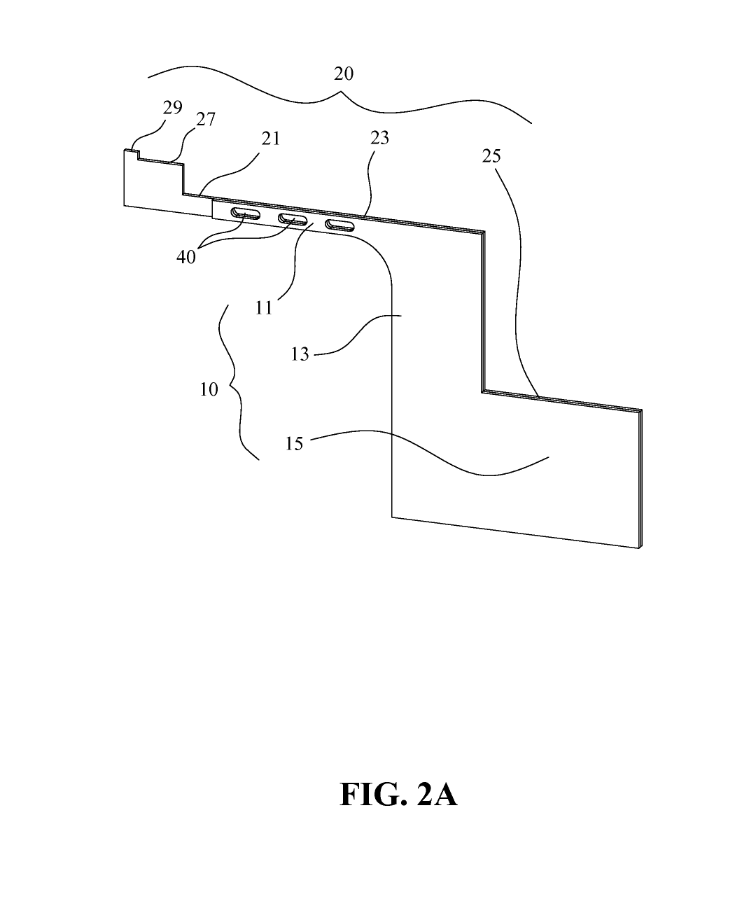

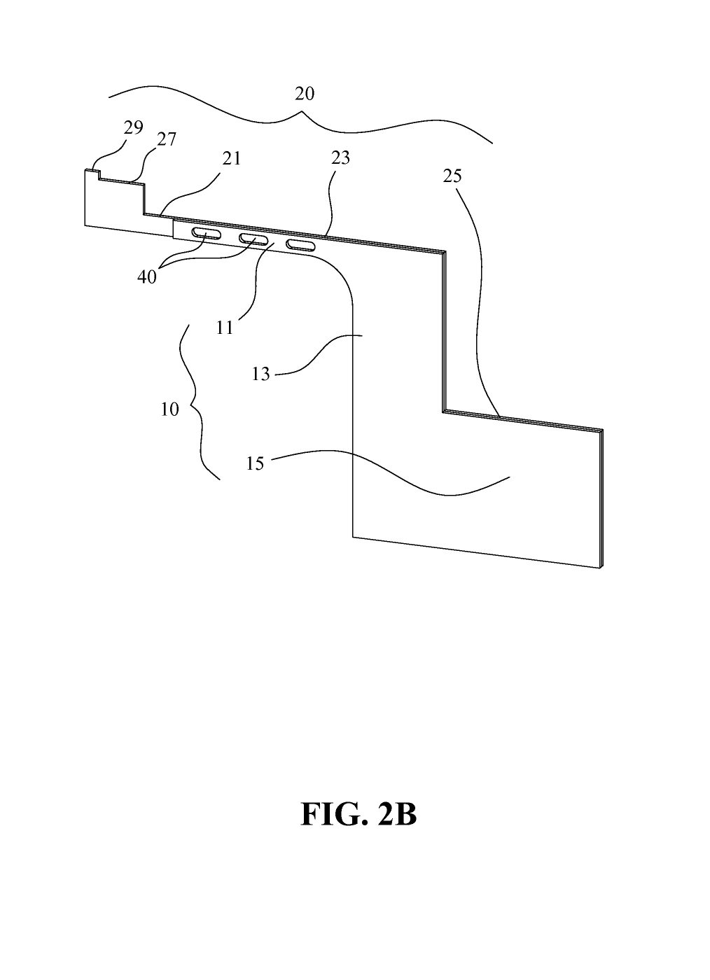

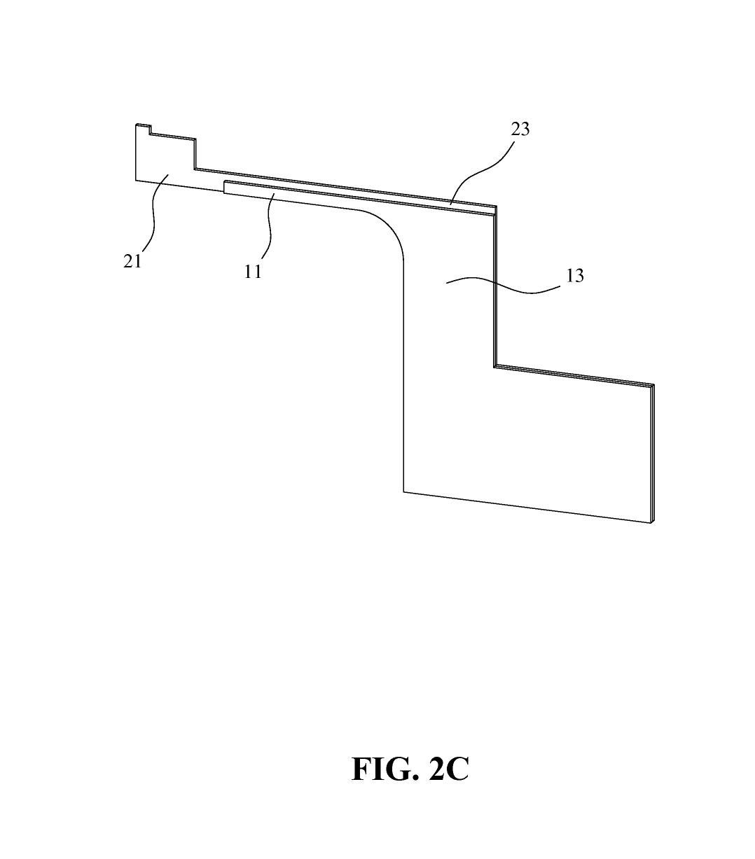

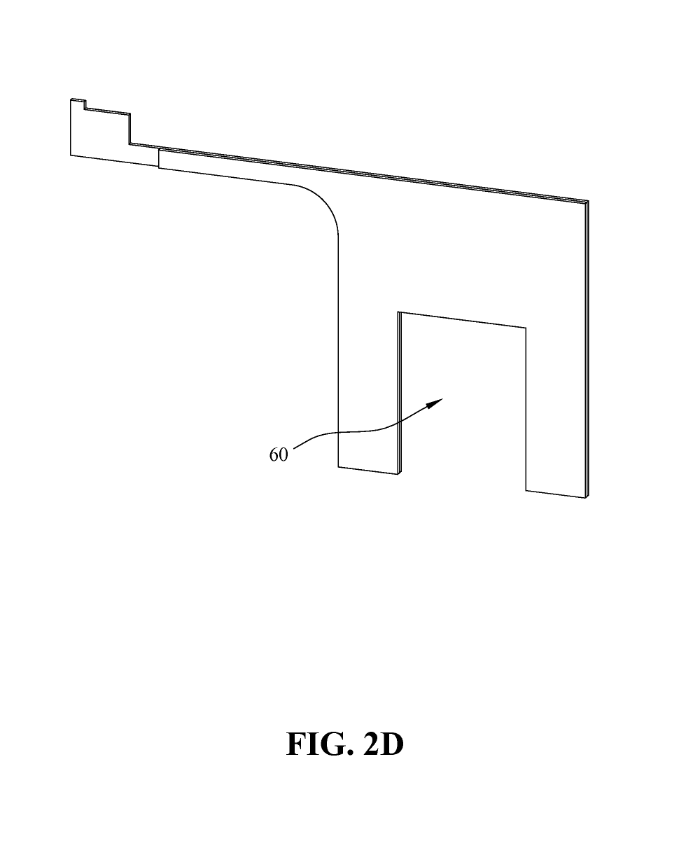

Refer to FIGS. 2A to 2D illustrating the perspective views of modification of the first embodiment of the blade type micro probe according to the present invention. As shown in FIGS. 2A and 2B, to adjust the mechanical properties, at least one slot 40 is provided at the first floating arm part 11 and the second floating arm part 21. The at least one slot 40 is implemented as shown in FIG. 2A by punching through the first floating arm part 11 and the second floating arm part 21, or as shown in FIG. 2B by only being formed in the surface of the first floating arm part 11. As shown in FIG. 2C, the second floating arm part 21 and the second connection part 23 have a width greater than that of the first floating arm part 11 and the first connection part 13. As shown in FIG. 2D, a fixed slot 60 is further provided on the first base part 15 and the second base part 25 to comply with some related mechanical design for being fixed and connected to an electrical conversion plate outside.

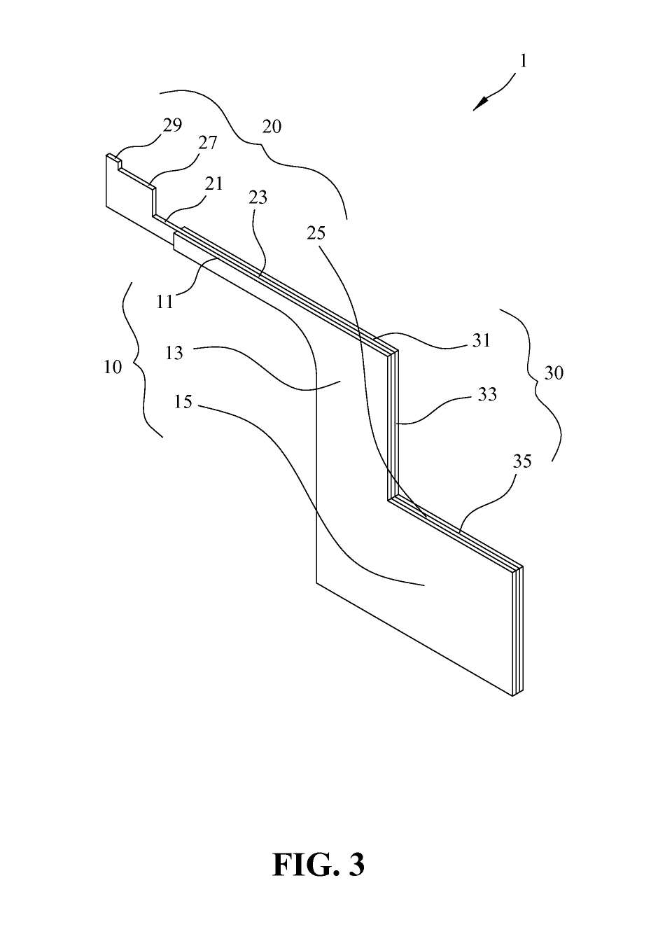

Refer to FIG. 3 illustrating a perspective view of the second embodiment of the blade type micro probe according to the present invention. As shown in FIG. 3, in addition to the first blade structure 10 and the second blade structure 20, the blade type micro probe 1 further includes a third blade structure 30 which is substantially identical to the first blade structure 10 in shape and is attached to two sides of the second blade structure 20 so as to form a three-layer stacked structure. The third blade structure 30 includes a third floating arm part 31, a third connection part 33 and a third base part 35, which are identical to the first floating arm part 11, the first connection part 13 and the first base part 15 in shape, respectively. Thus, the detailed description is omitted. The blade type micro probe 1 of the present invention has a thickness ranging 10˜100 nm, and the first blade structure 10, the second blade structure 20 and the third blade structure 30 are made of gold, copper, nickel, nickel-manganese alloy, nickel-iron alloy, nickel-cobalt alloy or lead-tin alloy.

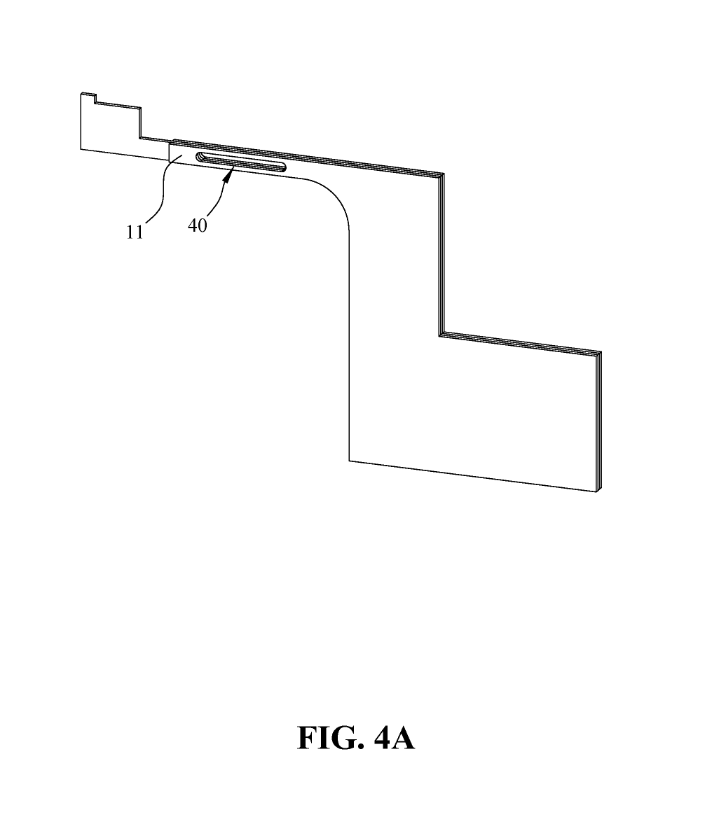

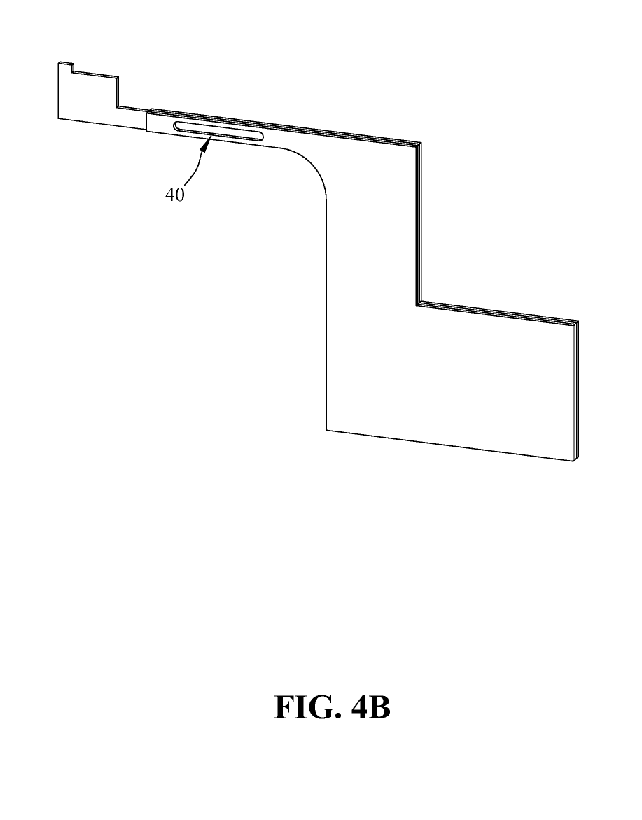

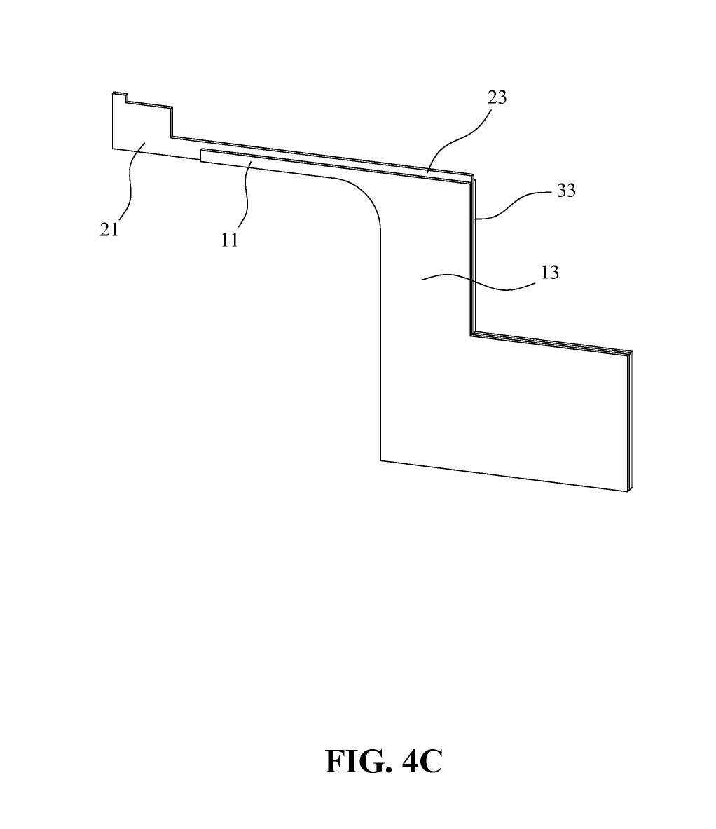

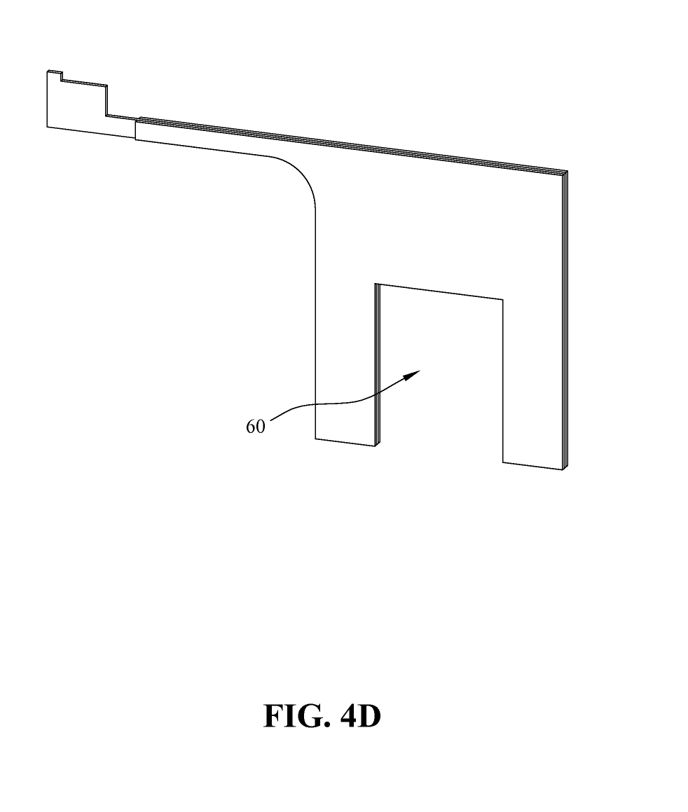

Refer to FIGS. 4A to 4D illustrating the perspective views of modification of the second embodiment of the blade type micro probe according to the present invention. As shown in FIGS. 4A and 4B, to adjust the mechanical properties, at least one slot 40 is formed through the first floating arm part 11, the second floating arm part 21 and the third floating arm part 31. The at least one slot 40 is implemented as shown in FIG. 4A by punching through the first floating arm part 11, the second floating arm part 21 and the third floating arm part 31, or as shown in FIG. 4B by only being formed in the side surface of the first floating arm part 11 and the third floating arm part 31 and being separated by the second floating arm part 21. As shown in FIG. 4C, the second floating arm part 21 and the second connection part 23 have a width greater than that of the first floating arm part 11, the first connection part 13, the third floating arm part 31 and the third connection part 33. As shown in FIG. 4D, a fixed slot 60 is further provided on the first base part 15, the second base part 25 and the third base part 35 to being connected to the electrical conversion plate outside.

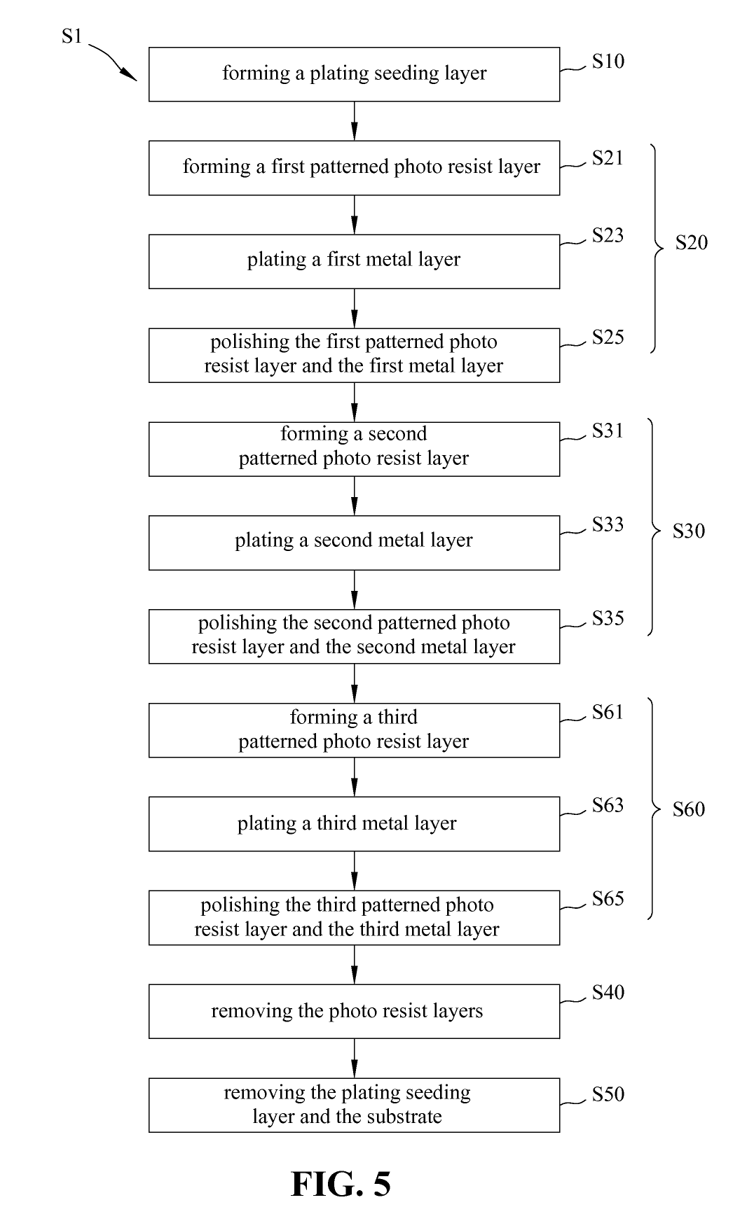

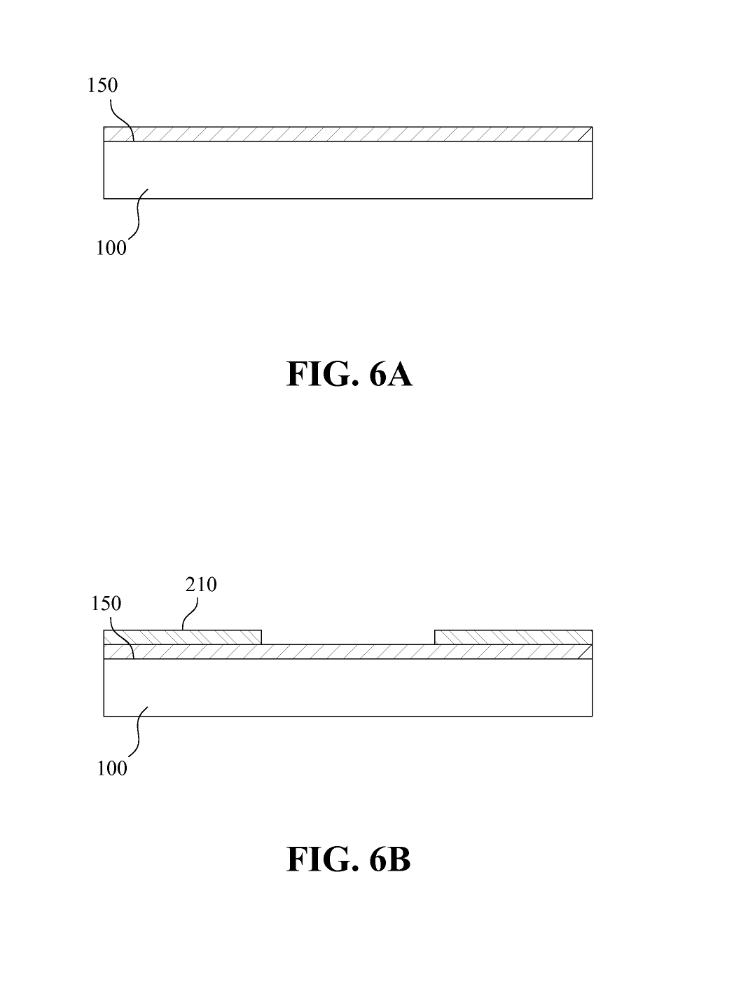

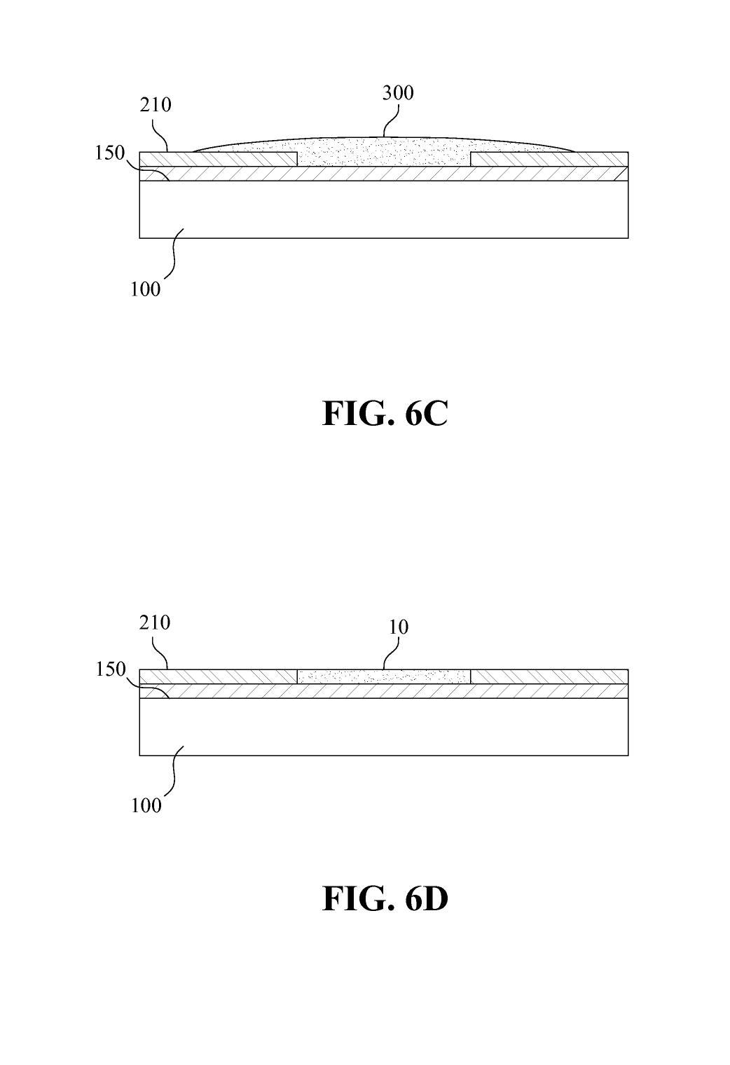

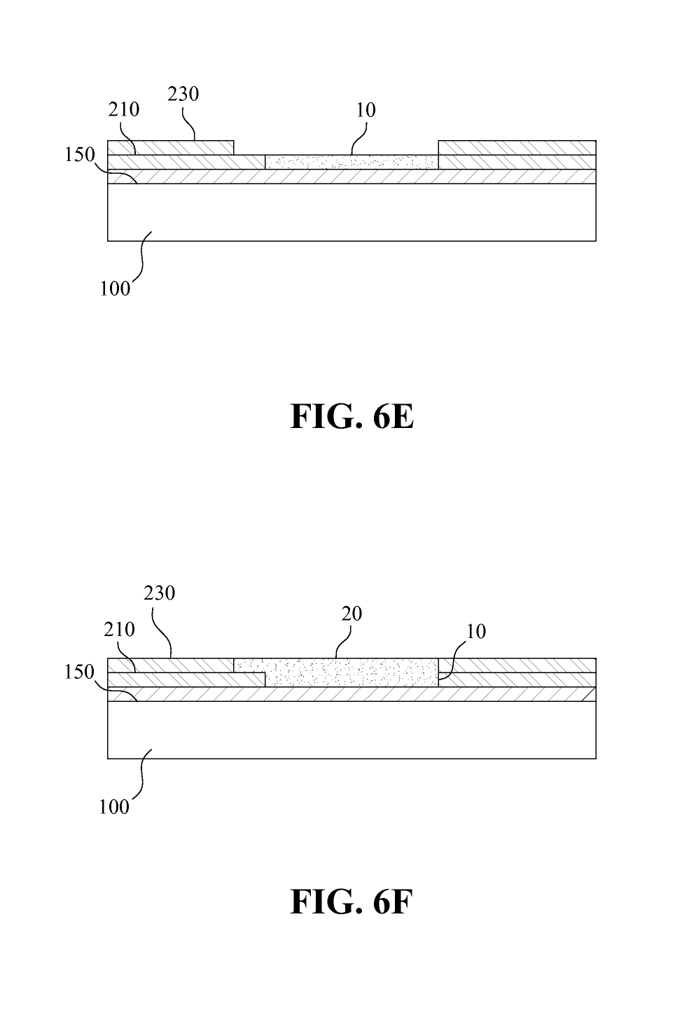

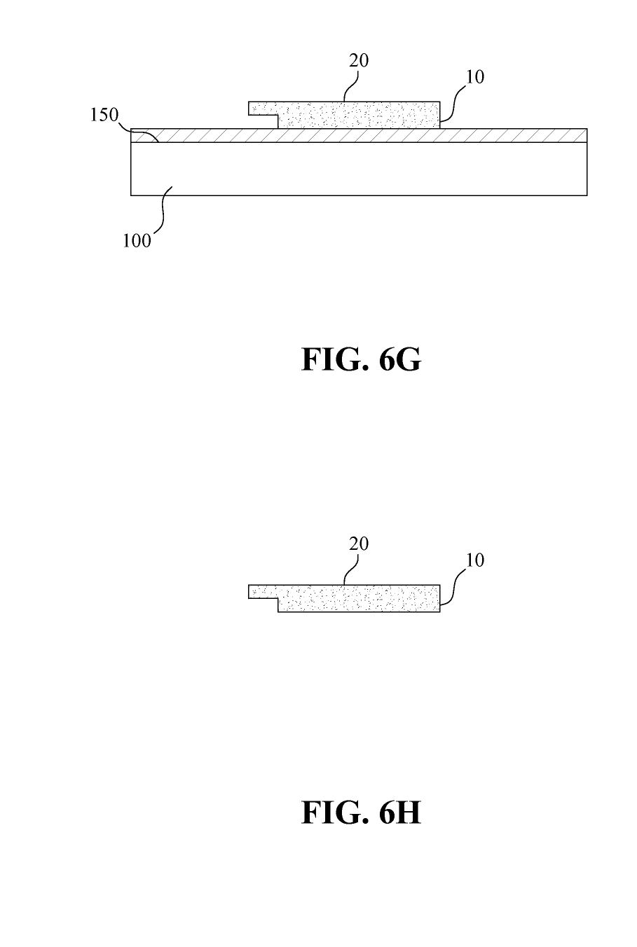

Refer to FIG. 5 illustrating a flow chart of the method of manufacturing the first embodiment of the blade type micro probe according to the present invention. As shown in FIG. 5, the method of the first embodiment includes the steps of S10, S20, S30, S40 and S50. In the step S10, the plating seed layer is formed on the substrate. Then, the first blade structure and the second blade structure are formed in the steps S20 and S30, respectively. The step S40 is to remove photo resist layer and finally the Step S50 is to remove the substrate and the plating seed layer. The step 20 includes the steps S21, S23 and S25, which are to form the first patterned photo resist layer, plate the first metal layer and perform the first polish process, respectively. Similarly, the step 30 includes the steps S31, S33 and S35, which are to form the second patterned photo resist layer, plate the second metal layer and perform the second polish process, respectively. The method of manufacturing the first embodiment of the blade type micro probe according to the present invention will be described in detail with reference to FIGS. 6A to 6H.

FIGS. 6A to 6H are sequentially cross sectional views of the first embodiment of the blade type micro probe manufactured by the method of the present invention. As FIG. 6A shown, the plating seed layer 150 is formed on the substrate 100 by performing a non-plating process, an evaporation deposition process or a sputtering process, and the plating seed layer 150 is made of at least one of gold, chromium, titanium, copper and wolfram. Preferably, the plating seed layer 150 is a two-layer structure with a lower metal layer and an upper metal layer, such as chromium/gold, titanium/gold, titanium/copper, or titanium-wolfram alloy/gold. Specifically, the lower metal layer in the two-layer structure has a thickness of 50˜200 Å, and the upper metal layer has a thickness of 500˜2000 Å.

The first patterned photo resist layer 210 is formed in the step S21 as shown in FIG. 6B by the image transfer process, and then in the step S23, the metal layer 300 is formed on the plating seed layer 150 and the first patterned photo resist layer 210 by plating, as shown in FIG. 6C, to fill up the voids in the first patterned photo resist layer 210. The first patterned photo resist layer 210 is made of gold, copper, nickel, nickel-manganese alloy, nickel-iron alloy, nickel-cobalt alloy or lead-tin alloy. Finally, as shown in FIG. 6D, the step S25, the process of grinding and polishing is performed to grind the metal layer 300 and the first patterned photo resist layer 210 to the same level, and the metal layer 300 filling up the voids is implemented as the first blade structure 10. The process of grinding and polishing is implemented by mechanical lapping, polishing or chemical mechanical polishing (CMP).

Subsequently, refer to FIGS. 6E to 6F. The step S30 includes the processes similar to those used in the step 20 to form the second blade structure 20 in the voids, of the second patterned photo resist layer 230. The second patterned photo resist layer 230 is different from the first patterned photo resist layer 210 in shape, and the second blade structure 20 and the first blade structure 10 are made of the same material or different material according to the requirement of the mechanical strength.

As shown in FIG. 6G, the step S40 used to remove the first patterned photo resist layer 210 and the second patterned photo resist layer 230 is implemented by use of a solvent or the plasma ash process. Then, in FIG. 6H, the step S60 is to remove the substrate 100 and remove the plating seed layer 150 by etching so as to form the blade type micro probe including the first blade structure 10 and the second blade structure 20. Specifically, the etching agent used to remove the plating seed layer 150 does not react with the blade type micro probe.

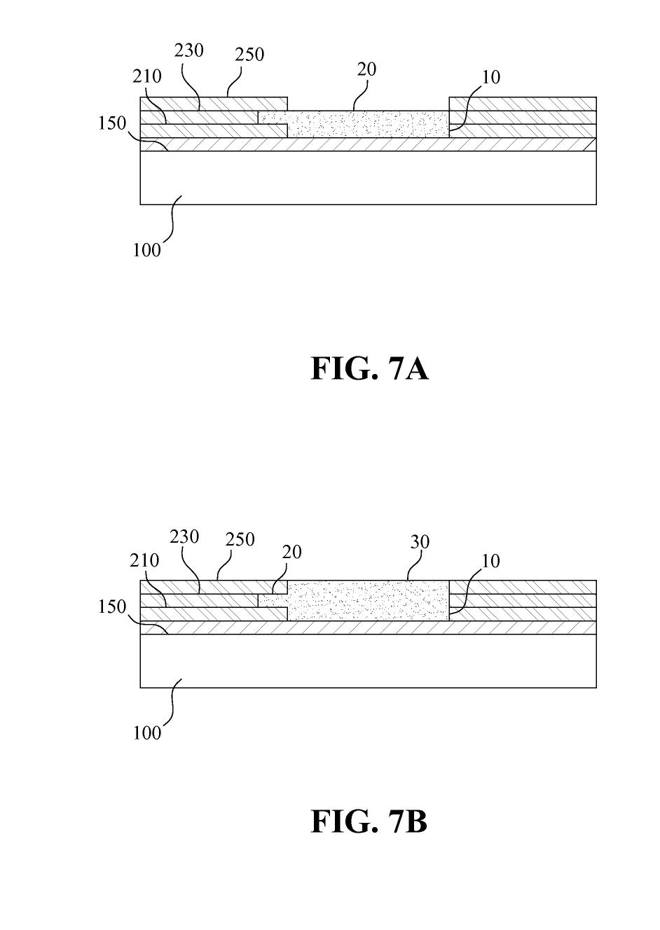

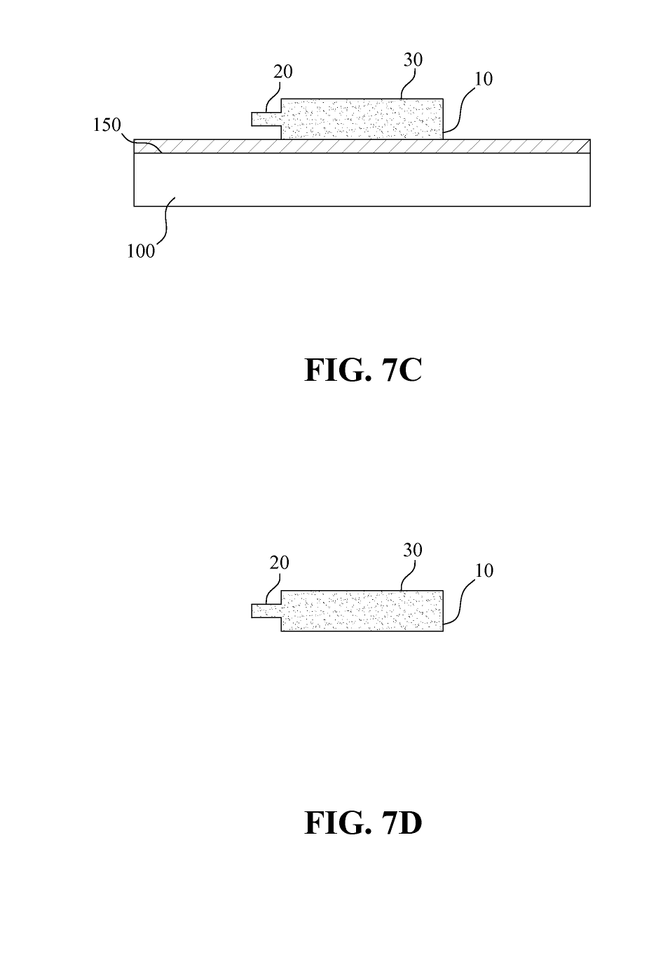

Again referring to FIG. 5, an additional Step S60 is included after the step S30 to form the third blade structure 30. The step S60 is similarly identical to the step S20, and includes the steps S61, S63 and S65, which will be described in detail with reference to FIGS. 7A and 7B.

As shown in FIGS. 7A and 7B, similar to the step S20, after the third patterned photo resist layer 250 is formed, the third blade structure 30 is formed by grinding and polishing the metal layer filling up the voids in the third patterned photo resist layer 250. Subsequently, as shown in FIG. 7C, the first patterned photo resist layer 210, the second patterned photo resist layer 230 and the third patterned photo resist layer 250 are removed. Finally, the substrate 100 is removed and the plating seed layer is etched to remove so as to form the blade type micro probe having the first blade structure 10, the second blade structure 20 and the third blade structure 30, as shown in FIG. 7D, wherein the third blade structure 30 is made of the material the same as or different from that of the second blade structure 20 and the first blade structure 10 depending on the requirement of the mechanical strength.

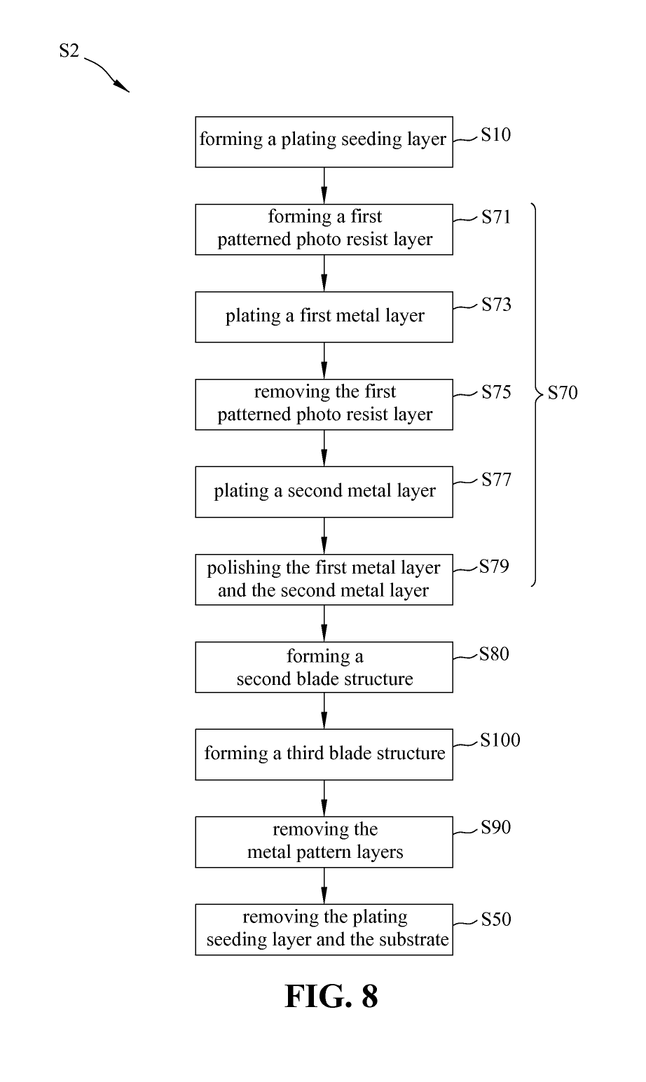

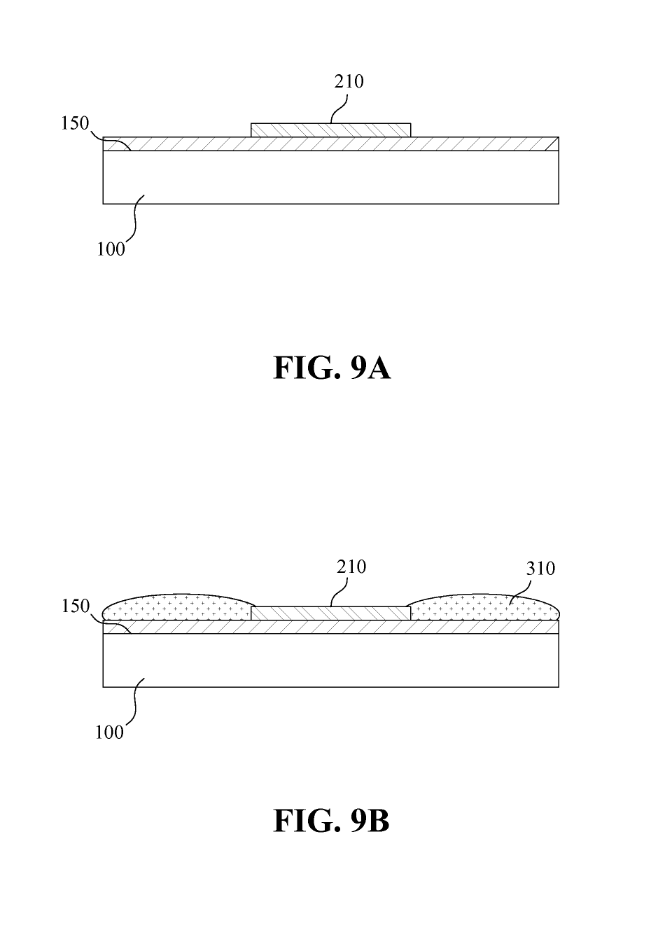

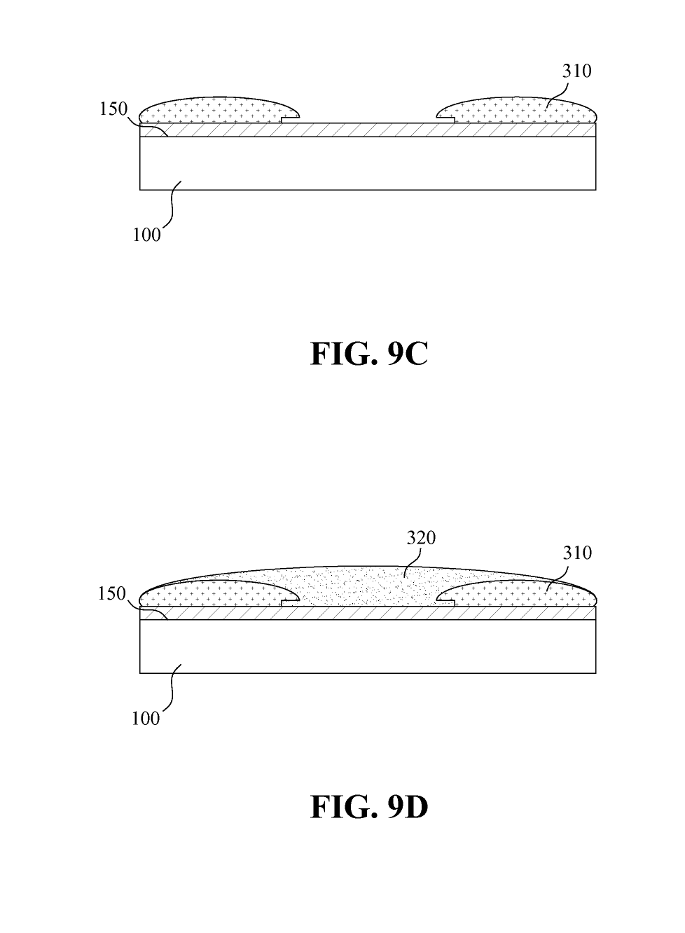

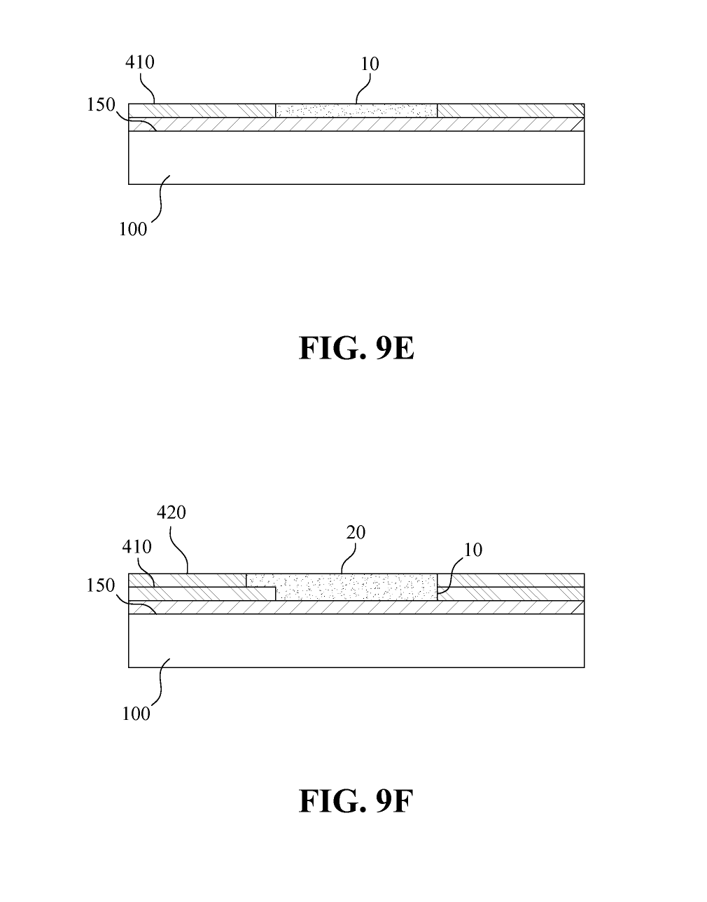

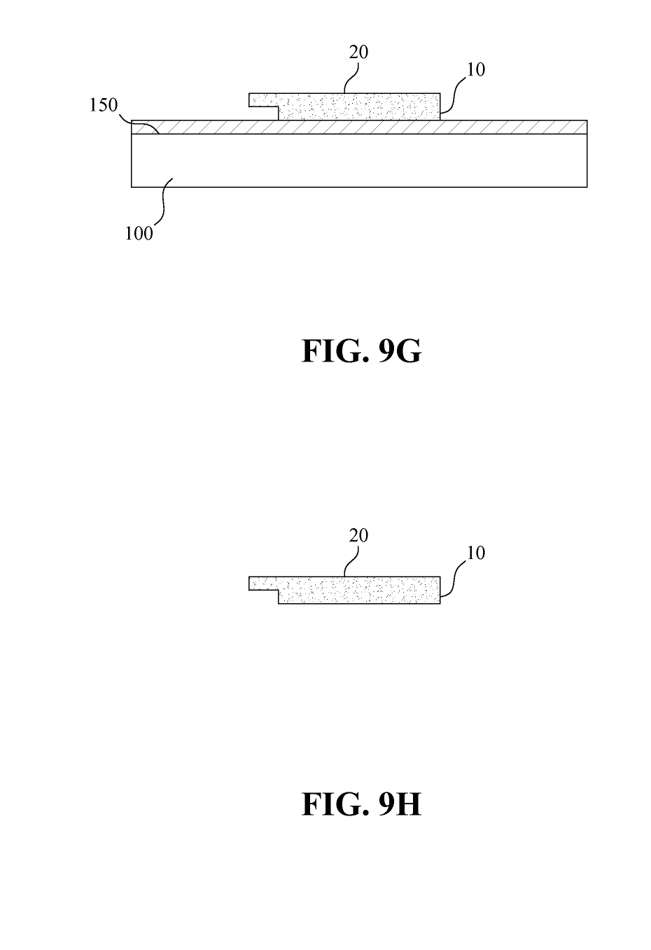

FIG. 8 illustrates a flow chart of the method of manufacturing the second embodiment of the blade type micro probe according to the present invention. As shown in FIG. 8, the method of the second embodiment includes the steps S10, S70, S80, S100 and S50. The steps S10 and S50 are the same as the above-mentioned first embodiment, and the description thereof is thus omitted. The step S70 used to form the first blade structure includes the steps S71, S73, S75, S77 and S79. The method of the second embodiment will be described in detail with reference to FIGS. 9A to 9H.

As shown in FIG. 7A, the step S71 is used to form the first patterned photo resist layer 210 on the plating seed layer 150 by the image transfer process. The step S73 is to form the first metal layer 310 on the plating seed layer 150 and the first patterned photo resist layer 210 by plating, as shown in FIG. 9B. The first metal layer 310 is formed of copper. Then in FIG. 9C, the step S75 is to remove the first patterned photo resist layer 210 by use of the solvent or the plasma ash process. The step S77 shown in FIG. 9D is to form the second metal layer 320 on the first metal layer 310 and the plating seed layer 150 exposed from the first patterned photo resist layer 210 just removed by plating. The second metal layer 320 fills up the space originally occupied by the first patterned photo resist layer 210, and is made of nickel, nickel-manganese alloy, nickel-iron alloy, nickel-cobalt alloy or lead-tin alloy. Finally, the step S79 is performed to grind the first metal layer 310 and the second metal layer 320 so as to form the first metal pattern layer 410 and the first blade structure 10 from the first metal layer 310 and the second metal layer 320, respectively, as shown in FIG. 9E. The first metal pattern layer 410 and the first blade structure 10 are co-planar.

As shown in FIG. 9F, the step S80 is performed similar to the step S70 to form the second metal pattern layer 420 and the second blade structure 20 on the first metal pattern layer 410 and the first blade structure 10. Then, the first metal pattern layer 410 and the second metal pattern layer 420 are removed by use of the etching agent, which does not react with the first blade structure 10 and the second blade structure 20, as shown in FIG. 9G. Finally, similar to the above first embodiment, the substrate 100 is removed and the plating seed layer 150 is then removed by etching so as to expose and form the blade type micro probe having the first blade structure 10 and the second blade structure 20 in the step S50, as shown in FIG. 9H.

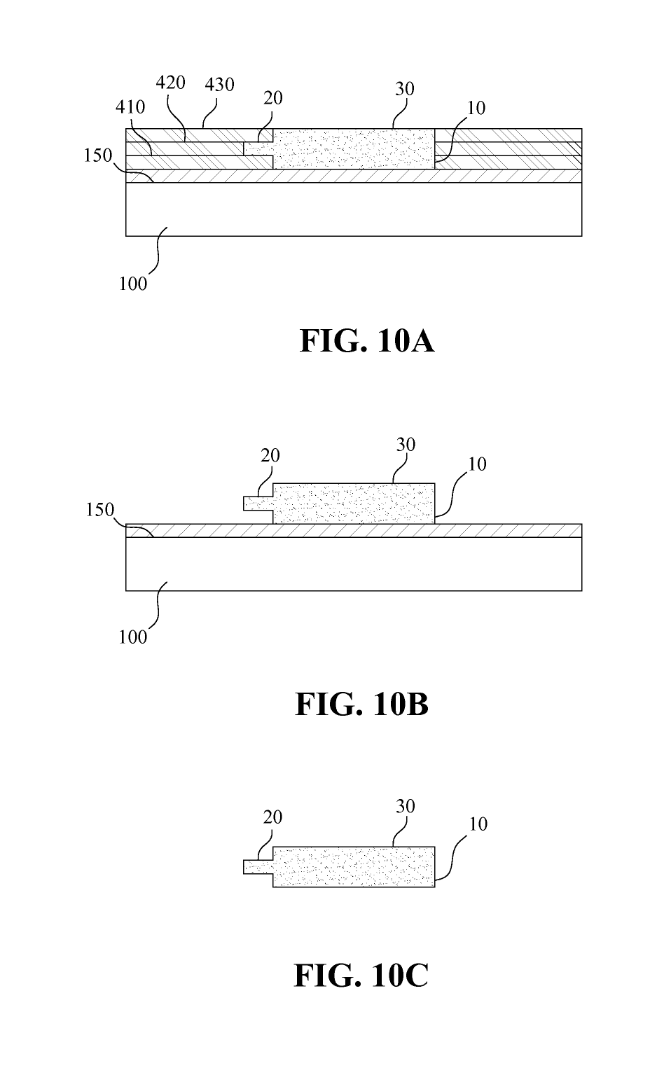

Returning to FIG. 8, after the step S80, the step S100 is additionally performed to form the third metal pattern layer 430 and the third blade structure 30 on the second metal pattern layer 420 and the second blade structure 20 similar to the step 70 as shown in FIG. 10A. Subsequently, the first metal pattern layer 410, the second metal pattern layer 420 and the third metal pattern layer 430 are removed by the etching agent which does not react with the first blade structure 10, the second blade structure 20, and the third blade structure 30, as shown in FIG. 10B. Finally, the substrate 100 is removed and the plating seed layer 150 is then removed by etching so as to expose and form the blade type micro probe having the first blade structure 10, the second blade structure 20 and the third blade structure 30, as shown in FIG. 10C. Specifically, the third metal pattern layer 430 and the first metal pattern layer 410 have the same shape, and the second metal pattern layer 420 and the first metal pattern layer 410 are different in shape. The first metal pattern layer 410, the second metal pattern layer 420 and the third metal pattern layer 430 are made of the same material, and the first blade structure 10, the second blade structure 20 and the third blade structure 30 are made of the same material or different materials depending on the requirement of the mechanical strength.

One feature of the present invention is that the blade type micro probe has a uniform structure and the force imposed on the blade type micro probe during the testing process is thus uniform to overcome the problem in the prior arts, where the force imposed is not uniform for the traditional epoxy probe card. Additionally, the method can be easily implemented in mass production to reduce the cost, and the blade type micro probe manufactured by the method of the present invention has a considerably small size to meet the requirement of the semiconductor testing, such as high pin counts and fine pitch.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A blade type micro probe, comprising:
a first blade structure including a first floating arm part, a first connection part and a first base part, wherein the first floating arm part has a shape of a strip and a width less than widths of the first connection part and the first base part, the first floating arm part extends from one side of the first connection part with a shape of a slab, and the first base part has a shape of a slab and extends from another side of the first connection part to connect to an electrical conversion plate outside; and
a second blade structure including a second floating arm part, a second connection part, a second base part, a pin socket and a contact part, wherein the second floating arm part, the second connection part and the second base part are attached to the first floating arm part, the first connection part and the first base part, respectively, the first base part and the second base part have the same shape and are located at the same position, the second floating arm part has a shape of a strip longer than the first floating arm part, the pin socket is provided at one end of the second floating part extends from the second connection arm part in an upward direction, and the contact part extends upward at the pin socket to contact with a bonding pad of a chip.

2. The blade type micro probe as claimed in claim 1, further comprising a third blade structure, wherein the third blade structure includes a third floating arm part, a third connection part and a third base part, which have shapes the same as the first floating arm part, the first connection part and the first base part, respectively, and the first blade structure and the third blade structure are closely and tightly stacked to two sides of the second blade structure, respectively.

3. The blade type micro probe as claimed in claim 2, wherein the blade type micro probe has a thickness ranging 10˜100 μm.

4. The blade type micro probe as claimed in claim 2, wherein the first blade structure, the second blade structure and the third blade structure are made of gold, copper, nickel, nickel-manganese alloy, nickel-iron alloy, nickel-cobalt alloy or lead-tin alloy.

5. The blade type micro probe as claimed in claim 1, wherein the first blade structure and the second blade structure are made of the same material.

6. The blade type micro probe as claimed in claim 1, wherein the first blade structure and the second blade structure are made of different materials.

7. The blade type micro probe as claimed in claim 2, wherein the third blade structure and the second blade structure are made of same material.

8. The blade type micro probe as claimed in claim 2, wherein the third blade structure and the second blade structure are made of different materials.

9. The blade type micro probe as claimed in claim 1, wherein the first floating arm part and the second floating arm part have at least one slot away from the pin socket, and the at least one slot of the first floating arm part and the at least one slot of the second floating arm part are spatially communicated with each other.

10. The blade type micro probe as claimed in claim 2, wherein the first floating arm part, the second floating arm part and the third floating arm part have at least one slot away from the pin socket, and the at least one slot of the first floating arm part and the at least one slot of the second floating arm part and the at least one slot of the third floating arm part are spatially communicated with one another.

11. The blade type micro probe as claimed in claim 1, wherein the first floating arm part has at least one slot.

12. The blade type micro probe as claimed in claim 2, wherein the first floating arm part and the third floating arm part have at least one slot, and the at least one slot of the first floating arm part and the at least one slot of the third floating arm part are symmetrically provided and separated by the second floating arm part.

13. The blade type micro probe as claimed in claim 1, further comprising an open slot formed through the first base part and the second base part.

14. The blade type micro probe as claimed in claim 1, wherein further comprising a fixed slot formed through the first base part, the second base part and the third base part.

15. The blade type micro probe as claimed in claim 1, wherein the second connection part and the second floating arm part have a width as same as widths of the first connection part and the first floating arm part.

16. The blade type micro probe as claimed in claim 1, wherein the second connection part and the second floating arm part have a width greater than widths of the first connection part and the first floating arm part.

17. The blade type micro probe as claimed in claim 2, wherein the second connection part and the second floating arm part have a width as same as widths of the first connection part and the third connection part, and widths of the first floating arm part and the third floating arm part.

18. The blade type micro probe as claimed in claim 2, wherein the second connection part and the second floating arm part have a width greater than widths of the first connection part and the third connection part, and widths of the first floating arm part and the third floating arm part.

19. A method of manufacturing a blade type micro probe, comprising:
a step of forming a plating seed layer on a substrate;
a step of forming a first blade structure by steps of forming a first patterned photo resist layer with voids on the plating seed layer, plating a metal layer to fill up the voids in the first patterned photo resist layer, and polishing the metal layer and the first patterned photo resist layer such that the metal layer and the first patterned photo resist layer have the same level and the first blade structure is formed by the polished metal layer;
a step of forming a second blade structure by steps of forming a second patterned photo resist layer with voids on the first patterned photo resist layer, plating an another metal layer to fill up the voids in the second patterned photo resist layer, and polishing the another metal layer and the second patterned photo resist layer such that the another metal layer and the second patterned photo resist layer have the same level and the second blade structure is formed by the polished another metal layer, wherein the first second patterned photo resist layer is different from the second patterned photo resist layer in shape;
a step of removing the first patterned photo resist layer and the second patterned photo resist layer by using a solvent or performing a plasma ash process;
a step of removing the substrate; and
a step of removing the plating seed layer by performing an etching process with an etching agent such that the blade type micro probe is formed, wherein the etching agent does not react with the blade type micro probe.

20. The method as claimed in claim 19, further comprising a step of forming a third blade structure after the step of forming the second blade structure by steps of forming a third patterned photo resist layer, plating a yet another metal layer and polishing the yet another metal layer and the third patterned photo resist layer, which are as similar to the step of forming the first blade structure, wherein the third patterned photo resist layer and the third blade structure are formed on the second patterned photo resist layer and the second blade structure, the third patterned photo resist layer and the first patterned photo resist layer have same shape such that the third patterned photo resist layer is removed as the first patterned photo resist layer and the second patterned photo resist layer are removed, and the blade type micro probe with the first blade structure, the second blade structure and the third blade structure is thus formed.

21. The method as claimed in claim 20, wherein the metal layer first blade structure and the second blade, and the third blade are made of gold, copper, nickel, nickel-manganese alloy, nickel-iron alloy, nickel-cobalt alloy or lead-tin alloy.

22. The method as claimed in claim 19, wherein the first blade structure and the second blade structure are made of the same material.

23. The method as claimed in claim 19, wherein the first blade structure and the second blade structure are made of different materials.

24. The method as claimed in claim 20, wherein the third blade structure and the second blade are made of the same material.

25. The method as claimed in claim 20, wherein the third blade structure and the second blade are made of different materials.

26. The method as claimed in claim 19, wherein the plating seed layer is formed by performing a non-plating process, an evaporation deposition process or a sputtering process, the plating seed layer is made of at least one of gold, chromium, titanium, copper and wolfram, and the plating seed layer further includes a two-layer structure with an upper metal layer and a lower metal layer.

27. The method as claimed in claim 26, wherein the upper metal layer is made of gold or copper, and has a thickness ranging 500˜2000 Å, and the lower metal layer is made of chromium, titanium or titanium-wolfram alloy, and has a thickness ranging 50˜200 Å.

28. A method of manufacturing a blade type micro probe, comprising:
a step of forming a plating seed layer on a substrate;
a step of forming a first blade structure by steps of forming a first patterned photo resist layer with voids on the plating seed layer, plating a first metal layer on the plating seed layer and the first patterned photo resist layer, removing the first patterned photo resist layer by a solvent or performing a plasma ash process, plating a second metal layer on the exposed plating seed layer to fill up an original space occupied by the first patterned photo resist layer, and polishing the first metal layer and the second metal layer such that the polished first metal layer forms a first metal pattern layer and the polished second metal layer forms the first blade structure, wherein the first metal pattern layer and the first blade structure are co-planar;
a step of forming a second metal pattern layer and a second blade structure on the first metal pattern layer and the first blade structure by steps of forming a second patterned photo resist layer with voids on the first metal pattern layer and the first blade structure, plating the first metal layer on the first metal pattern layer, the first blade structure and the second patterned photo resist layer, removing the second patterned photo resist layer by the solvent or performing the plasma ash process, plating the second metal layer on the first metal pattern layer and the first blade structure to fill up an original space occupied by the second patterned photo resist layer, and polishing the first metal layer and the second metal layer, which are as similar to the step of forming the first blade structure, wherein the second metal pattern layer and the second blade structure are co-planar and the second metal pattern layer is different from the first metal pattern layer in shape;
a step of removing the first metal pattern layer and the second metal pattern layer by an etching agent, wherein the etching agent does not react with the first blade structure and the second blade structure;
a step of removing the substrate; and
a step of removing the plating seed layer by performing an etching process with an another etching agent to form the blade type micro probe with the first blade structure and the second blade structure, wherein the another etching agent does not react with the blade type micro probe.

29. The method as claimed in claim 28, wherein further comprising a step of forming a third metal pattern and a third blade structure on the second metal pattern layer and the second blade structure by steps of forming a third patterned photo resist layer with voids on the second metal pattern layer and the second blade structure, plating the first metal layer on the second metal pattern layer, the second blade structure and the third patterned photo resist layer, removing the third patterned photo resist layer by the solvent or performing the plasma ash process, plating a second metal layer on the second metal pattern layer and the second blade structure to fill up an original space occupied by the third patterned photo resist layer, and polishing the first metal layer and the second metal layer, which are similar to the step of forming the first blade structure, wherein the third metal pattern layer and the third blade structure are co-planar and third metal pattern layer is the same as the first metal pattern layer in shape, such that the third metal pattern layer is removed as the first metal pattern layer and the second metal pattern layer are removed, and the blade type micro probe with the first blade structure, the second blade structure and the third blade structure is thus formed.

30. The method as claimed in claim 28, wherein the first blade structure and the second blade structure are made of the same material.

31. The method as claimed in claim 28, wherein the first blade structure and the second blade structure are made of different materials.

32. The method as claimed in claim 29, wherein the third blade structure and the second blade structure are made of the same material.

33. The method as claimed in claim 29, wherein the third blade structure and the second blade structure are made of different materials.

34. The method as claimed in claim 28, wherein the plating seed layer is formed by performing a non-plating process, an evaporation deposition process or a sputtering process, the plating seed layer is made of at least one of gold, chromium, titanium, copper and wolfram, and the plating seed layer further includes a two-layer structure with an upper metal layer and a lower metal layer.

35. The method as claimed in claim 34, wherein the upper metal layer is made of gold or copper, and has ranging thickness of 500˜2000 Å, and the lower metal layer is made of chromium, titanium or titanium-wolfram alloy, and has a thickness ranging 50˜200 Å.

36. The method as claimed in claim 28, wherein the first metal layer is made of copper, and the second metal layer is made of nickel, nickel-manganese alloy, nickel-iron alloy, nickel-cobalt alloy or lead-tin alloy.
